(19) United States
(12) Patent Application Publication
(10) Pub. No.: US 2002/0070443 A1
(43) Pub. Date: Jun. 13, 2002

(54) Microelectronic package having an integrated heat sink and build-up layers

(76) Inventors: Xiao-Chun Mu, Saratoga, CA (US); Qing Ma, San Jose, CA (US); Maria V. Henao, Pleasanton, CA (US); Steven Towle, Sunnyvale, CA (US); Quat T. Vu, Santa Clara, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/733,289

(22) Filed: Dec. 8, 2000

(51) Int. Cl. H01L 21/50; H01L 21/44; H01L 23/28

(52) U.S. Cl. 257/712; 257/796; 438/122

(57) ABSTRACT

A microelectronic package fabrication technology that attaches at least one microelectronic die onto a heat spreader and encapsulates the microelectronic die/dice thereon which may further include a microelectronic packaging core abutting the heat spreader wherein the microelectronic die/dice reside within at least one opening in a microelectronic package core. After encapsulation, build-up layers may be fabricated to form electrical connections with the microelectronic die/dice.

### BACKGROUND OF THE INVENTION

1. Field of the Invention

The present invention relates to apparatus and processes for the fabrication of a microelectronic package. In particular, the present invention relates to a fabrication technology that attaches at least one microelectronic die to a heat spreader and encapsulates the microelectronic dice thereon.

2. State of the Art

Higher performance, lower cost, increased miniaturization of integrated circuit components, and greater packaging density of integrated circuits are ongoing goals of the computer industry. As these goals are achieved, microelectronic dice become smaller. Of course, the goal of greater packaging density requires that the entire microelectronic die package be equal to or only slightly larger (about 10% to 30%) than the size of the microelectronic die itself. Such microelectronic die packaging is called a “chip scale packaging” or “CSP”.

As shown in FIG. 27, true CSP involves fabricating build-up layers directly on an active surface 204 of a microelectronic die 202. The build-up layers may include a dielectric layer 206 disposed on the microelectronic die active surface 204. Conductive traces 208 may be formed on the dielectric layer 206, wherein a portion of each conductive trace 208 contacts at least one contact 212 on the active surface 204. External contacts, such as solder balls or conductive pins for contact with an external component (not shown), may be fabricated to electrically contact at least one conductive trace 208. FIG. 27 illustrates the external contacts as solder balls 214 which are surrounded by a solder mask material 216 on the dielectric layer 206. However, in such true CSP, the surface area provided by the microelectronic die active surface 204 generally does not provide enough surface for all of the external contacts needed to contact the external component (not shown) for certain types of microelectronic dice (e.g., logic).

Additional surface area can be provided through the use of an interposer, such as a substrate (substantially rigid material) or a flex component (substantially flexible material). FIG. 28 illustrates a substrate interposer 222 having a microelectronic die 224 attached to and in electrical contact with a first surface 226 of the substrate interposer 222 through small solder balls 228. The small solder balls 228 extend between contacts 232 on the microelectronic die 224 and conductive traces 234 on the substrate interposer first surface 226. The conductive traces 234 are in discrete electrical contact with bond pads 236 on a second surface 238 of the substrate interposer 222 through vias 242 that extend through the substrate interposer 222. External contacts 244 (shown as solder balls) are formed on the bond pads 236. The external contacts 244 are utilized to achieve electrical communication between the microelectronic die 224 and an external electrical system (not shown).

The use of the substrate interposer 222 requires a number of processing steps. These processing steps increase the cost of the package. Additionally, even the use of the small solder balls 228 presents crowding problems which can result in shorting between the small solder balls 228 and can present difficulties in inserting underfill material between the microelectronic die 224 and the substrate interposer 222 to prevent contamination and provide mechanical stability. Furthermore, current packages may not meet power delivery requirements for future microelectronic dice 224 due to thickness of the substrate interposer 222, which causes land-side capacitors to have too high an inductance.

FIG. 29 illustrates a flex component interposer 252 wherein an active surface 254 of a microelectronic die 256 is attached to a first surface 258 of the flex component interposer 252 with a layer of adhesive 262. The microelectronic die 256 is encapsulated in an encapsulation material 264. Openings are formed in the flex component interposer 252 by laser ablation through the flex component interposer 252 to contacts 266 on the microelectronic die active surface 254 and to selected metal pads 268 residing within the flex component interposer 252. A conductive material layer is formed over a second surface 272 of the flex component interposer 252 and in the openings. The conductive material layer is patterned with standard photomask/etch processes to form conductive vias 274 and conductive traces 276. External contacts are formed on the conductive traces 276 (shown as solder balls 248 surrounded by a solder mask material 282 proximate the conductive traces 276).

The use of a flex component interposer 252 requires gluing material layers which form the flex component interposer 252 and requires gluing the flex component interposer 252 to the microelectronic die 256. These gluing processes are relatively difficult and increase the cost of the package. Furthermore, the resulting packages have been found to have poor reliability.

Therefore, it would be advantageous to develop new apparatus and techniques to provide additional surface area to form traces for use in CSP applications, which overcomes the above-discussed problems.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1-4 are side cross-sectional views illustrating steps in a method of forming a microelectronic structure, according to the present invention;

FIGS. 5-11 are side cross-sectional views illustrating an embodiment of fabricating another embodiment of a microelectronic structure, according to the present invention;

FIGS. 12-19 are side cross-sectional views of a method of fabricating build-up layers on a microelectronic structure, according to the present invention;

FIGS. 20 and 21 are side cross-sectional views of an embodiment of fabricating yet another embodiment of a microelectronic structure, according to the present invention;

FIGS. 22 and 23 are side cross-sectional views of the microelectronic packages with a microelectronic package core, according to the present invention;

FIG. 24 is a side cross-sectional view of a multi-chip module, according to the present invention;

FIGS. 25 and 26 are side cross-sectional views of the microelectronic packages without a microelectronic package core, according to the present invention;

FIG. 27 is a side cross-sectional view of a true CSP of a microelectronic device, as known in the art;

FIG. 28 is a cross-sectional view of a CSP of a microelectronic device utilizing a substrate interposer, as known in the art; and

FIG. 29 is a cross-sectional view of a CSP of a microelectronic device utilizing a flex component interposer, as known in the art.

### DETAILED DESCRIPTION OF THE ILLUSTRATED EMBODIMENTS

In the following detailed description, reference is made to the accompanying drawings that show, by way of illustration, specific embodiments in which the invention may be practiced. These embodiments are described in sufficient detail to enable though skilled in the art to practice the invention. It is to be understood that the various embodiments of the invention, although different, are not necessarily mutually exclusive. For example, a particular feature, structure, or characteristic described herein, in connection with one embodiment, may be implement within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

The present invention includes a microelectronic package fabrication technology that attaches at least one microelectronic die onto a heat spreader and encapsulates the microelectronic die/dice thereon. The present invention may further include a microelectronic packaging core abutting the heat spreader wherein the microelectronic die/dice reside within at least one opening in a microelectronic package core and an encapsulation material secures the microelectronic die/dice within the opening(s). After encapsulation, build-up layers may be fabricated to form electrical connections with the microelectronic die/dice.

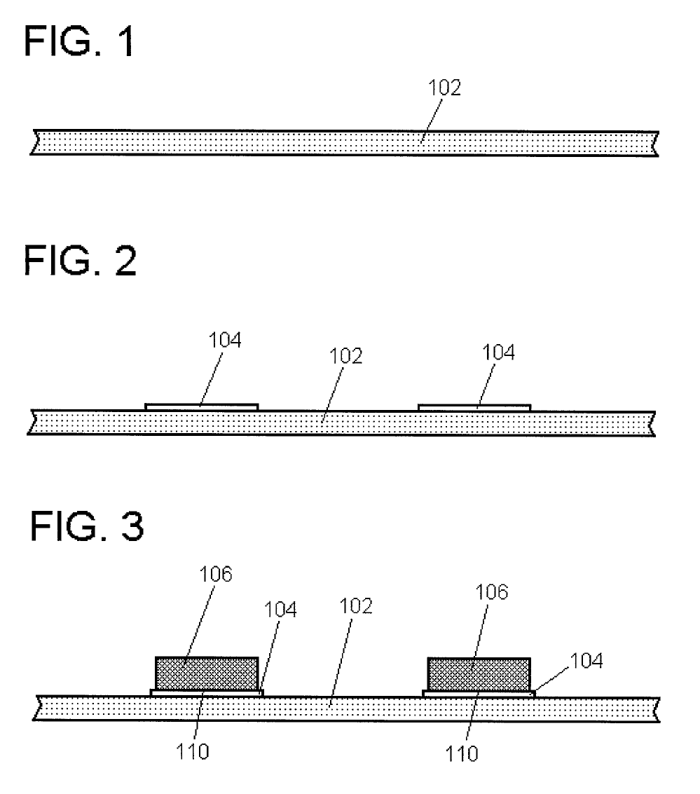

FIGS. 1-4 illustrate step in a method for fabricating a microelectronic structure. As shown in FIG. 1, a substantially planar heat sink 102 is provided. The heat sink 102 preferably comprises a highly thermally conductive material, which may include, but is not limited to, metals, such as copper, copper alloys, molybdenum, molybdenum alloys, aluminum, aluminum alloys, and the like. The material used to fabricate the heat spreader 102 may also include, but is not limited to, thermally conductive ceramic materials, such as AlSiC, A1N, and the like. It is further understood that the heat spreader 102 could be a more complex device such as a heat pipe or a plurality of small heat pipes within the heat sink.

As shown in FIG. 2, an adhesive layer 104, preferably thermally conductive, is patterned on the heat sink 102. The adhesive layer 104 may comprise a resin or epoxy material filled with thermally conductive particulate material, such as silver or aluminum nitride. The adhesive layer 104 may also comprise metal and metal alloys having low melting temperature (e.g., solder materials), and the like.

A back surface 110 of at least one microelectronic die 106 is placed on the adhesive layer 104 to attach it to the heat sink 102, as shown in FIG. 3. Preferably, the adhesive layer 104 is patterned to the approximate size of the microelectronic die 106. The microelectronic dice 106 may be any known active or passive microelectronic device including, but not limited to, logic (CPUs), memory (DRAM, SRAM, SDRAM, etc.), controllers (chip sets), capacitors, resistors, inductors, and the like. The microelectronic dice 106 are preferably tested, electrically and/or otherwise, to eliminate non-functioning dice prior to use.

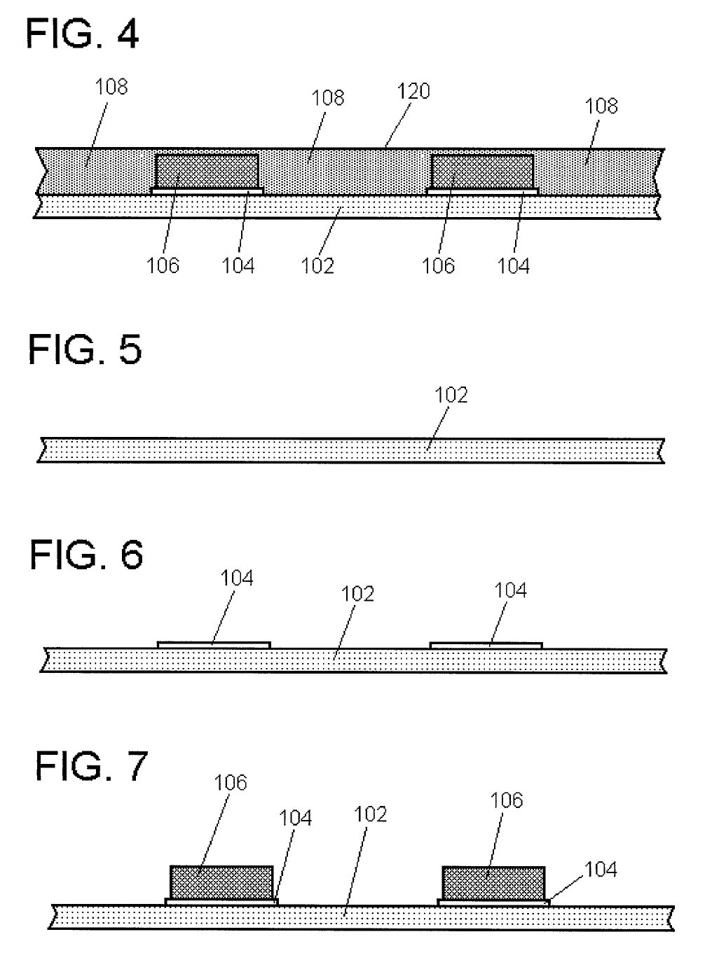

As shown in FIG. 4, a dielectric encapsulation material 108, such as, such as plastics, resins, epoxies, elastomeric (e.g., rubbery) materials, and the like, is deposited over the microelectronic dice 106 and heat spreader 102. The dielectric encapsulation material 108 should be chosen sufficiently viscous for filling and for forming a substantially planar upper surface 120.

FIGS. 5-11 illustrates an embodiment of fabricating another embodiment of a microelectronic structure. As shown in FIG. 5, a substantially planar heat sink 102 is provided. As shown in FIG. 6, an adhesive layer 104, preferably thermally conductive, is patterned on the heat sink 102. The back surface 110 of at least one microelectronic die 106 is placed on the adhesive layer 104 to attach it to the heat sink 102, as shown in FIG. 7.

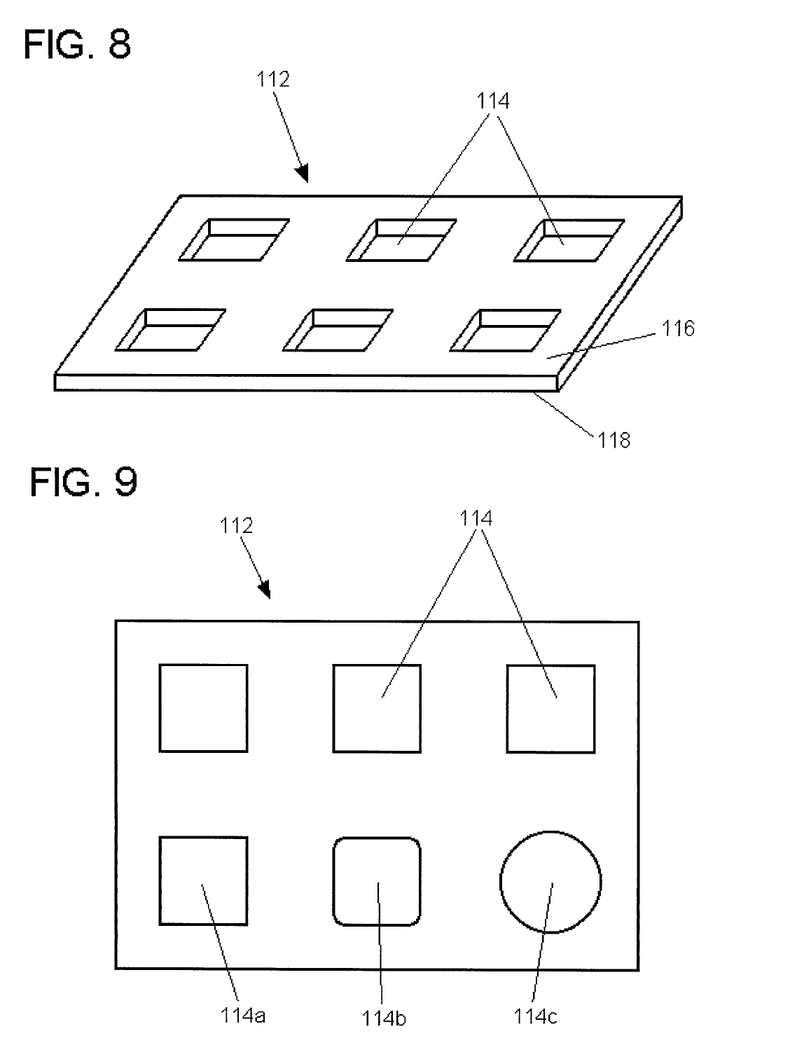

FIGS. 8-9 illustrates a microelectronic package core 112 used to fabricate the microelectronic device of the present embodiment. The microelectronic package core 112 preferably comprises a substantially planar material. The material used to fabricate the microelectronic package core 112 may include, but is not limited to, a Bismaleimide Triazine (“BT”) resin based laminate material, an FR4 laminate material (a flame retarding glass/epoxy material), various polyimide laminate materials, ceramic material, and the like, and metallic materials (such as copper) and the like. The microelectronic package core 112 has at least one opening 114 extending therethrough from a first surface 116 of the microelectronic package core 112 to an opposing second surface 118 of the microelectronic package core 112. As shown in FIG. 9, the opening(s) 114 may be of any shape and size including, but not limited to, rectangular/square 114a, rectangular/square with rounded corners 114b, and circular 114c. The only limitation on the size and shape of the opening(s) 114 is that they must be appropriately sized and shaped to house a corresponding microelectronic die or dice therein, as will be discussed below.

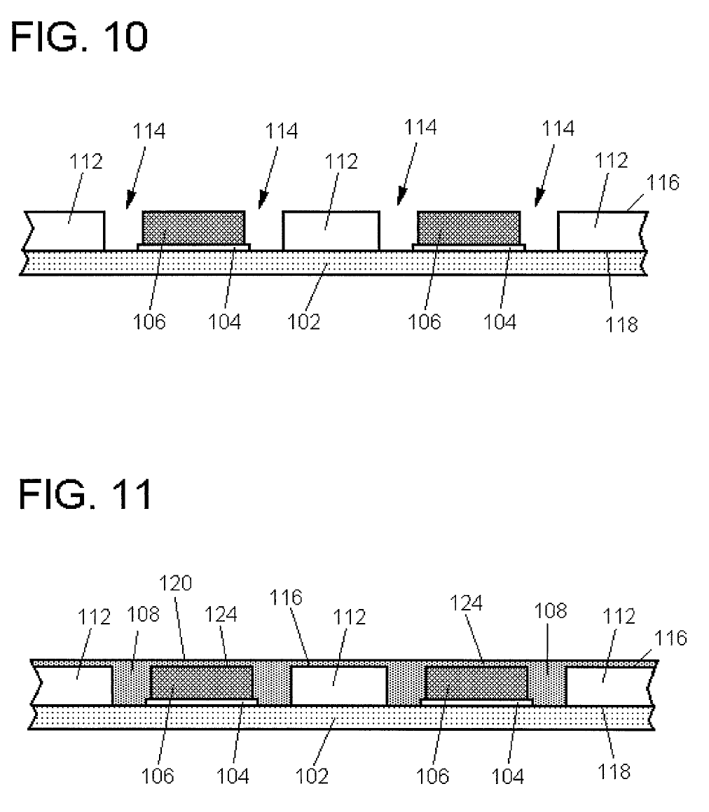

As shown in FIG. 10, the second surface microelectronic package core 118 is placed on the heat spreader 102. The openings 114 are positioned such that the microelectronic dice 106 reside therein. The dielectric encapsulation material 108 is then deposited over the microelectronic dice 106 (covering an active surface 124 thereof), the microelectronic package core 112 (covering first surface 116 thereof), and in portions of the openings 114 (see FIG. 10) not occupied by the microelectronic die 106, as shown in FIG. 11. The dielectric encapsulation material 108 secures the microelectronic die 106 within the microelectronic package core 112 and provides surface area for subsequent formation of build-up layers.

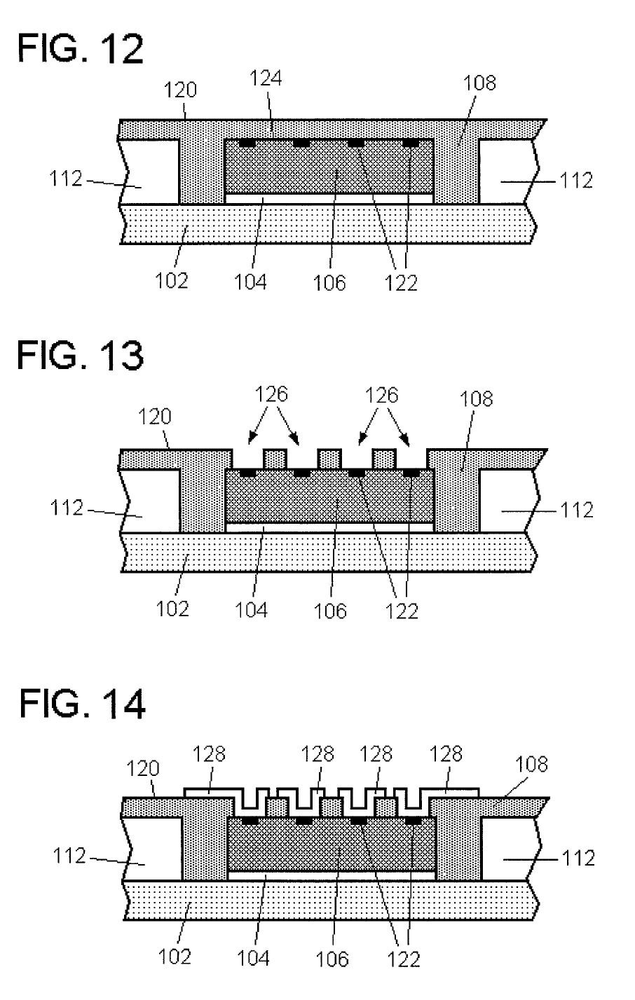

FIG. 12 illustrates a view of a single microelectronic die 106 encapsulated with the dielectric encapsulation material 108 within the microelectronic package core 112. The microelectronic die 106, of course, includes a plurality of electrical contacts 122 located on the active surface 124 thereof. The electrical contacts 122 are electrically connected to circuitry (not shown) within the microelectronic die 106. Only four electrical contacts 122 are shown for sake of simplicity and clarity.

As shown in FIG. 13, a plurality of vias 126 are then formed through the dielectric encapsulation material 108 covering the microelectronic die active surface 124. The plurality of vias 126 are preferably formed by laser drilling, but could be formed by any method known in the art, including but not limited to photolithography.

A plurality of conductive traces 128 is formed on the dielectric encapsulation material upper surface 120, as shown in FIG. 14, wherein a portion of each of the plurality of conductive trace 128 extends into at least one of said plurality of vias 126 (see FIG. 13) to make electrical contact therewith. The plurality of conductive traces 128 may be made of any applicable conductive material, such as copper, aluminum, and alloys thereof.

The plurality of conductive traces 128 may be formed by any known technique, including but not limited to semi-additive plating and photolithographic techniques. An exemplary semi-additive plating technique can involve depositing a seed layer, such as sputter-deposited or electroless-deposited metal on the dielectric encapsulation material 108. A resist layer is then patterned on the seed layer followed by electrolytic plating of a layer of metal, such as copper, on the seed layer exposed by open areas in the patterned resist layer. The patterned resist layer is stripped and portions of the seed layer not having the layer of metal plated thereon is etched away. Other methods of forming the plurality of conductive traces 128 will be apparent to those skilled in the art.

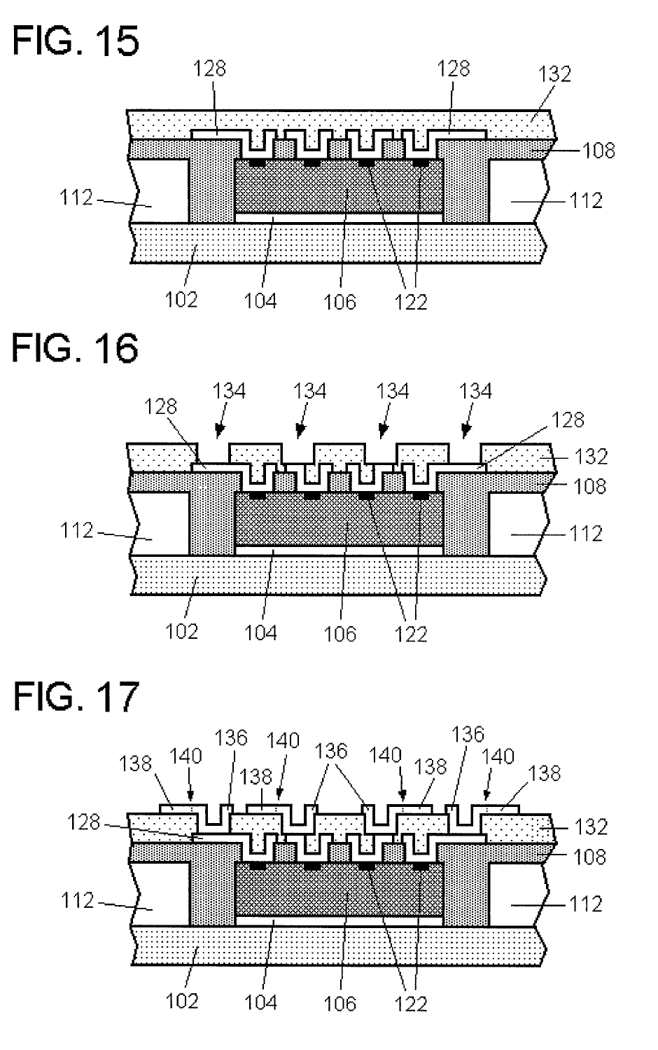

As shown in FIG. 15, a dielectric layer 132, such as epoxy resin, polyimide, bisbenzocyclobutene, and the like, is disposed over the plurality of conductive traces 128 and the dielectric encapsulation material 108. The formation of the dielectric layer 132 may be achieved by any known process, including but not limited to film lamination, spin coating, roll coating and spray-on deposition. The dielectric layers of the present invention are preferably filled epoxy resins available from Ibiden U.S.A. Corp., Santa Clara, Calif., U.S.A. and Ajinomoto U.S.A., Inc., Paramus, N.J., U.S.A.

As shown in FIG. 16, a plurality of second vias 134 is then formed through the dielectric layer 132. The plurality of second vias 134 is preferably formed by laser drilling, but may be formed any method known in the art.

If the plurality of conductive traces 128 is not capable of placing the plurality of second vias 134 in an appropriate position, or if the routing is constrained in such a way that key electrical performance requirements such as power delivery, impedance control and cross talk minimization cannot be met, then other portions of the conductive traces are formed in the plurality of second vias 134 and on the dielectric layer 132, another dielectric layer formed thereon, and another plurality of vias is formed in the dielectric layer, such as described in FIGS. 14-16. The layering of dielectric layers and the formation of conductive traces can be repeated until the vias are in an appropriate position and electrical performance requirements are met. Thus, portions of a single conductive trace be formed from multiple portions thereof and can reside on different dielectric layers.

A second plurality of conductive traces 136 may be formed, wherein a portion of each of the second plurality of conductive traces 136 extends into at least one of said plurality of second vias 132. The second plurality of conductive traces 136 each include a landing pad 138 (an enlarged area on the traces demarcated by a dashed line 140), as shown in FIG. 17.

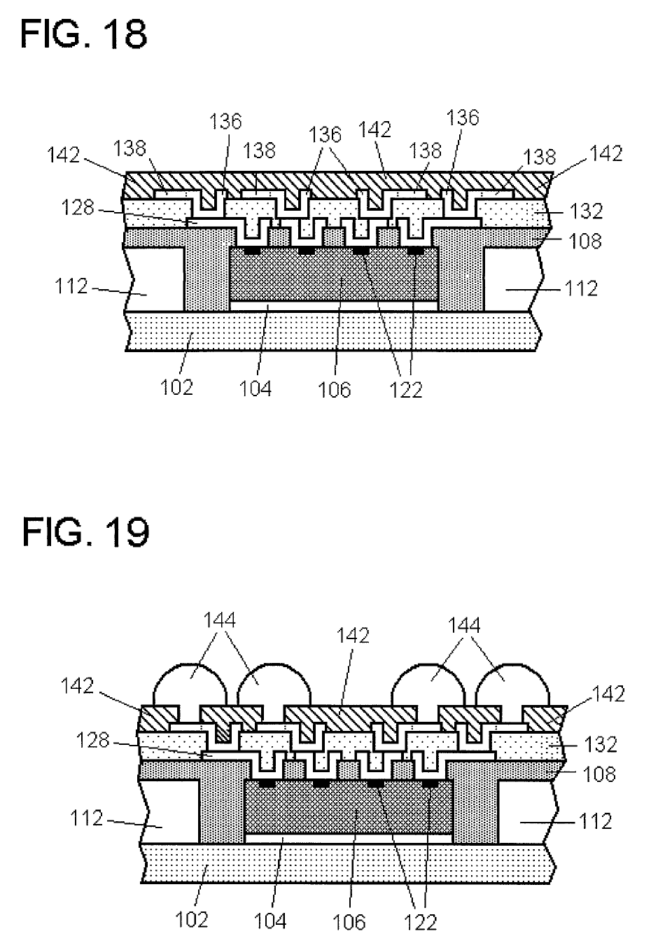

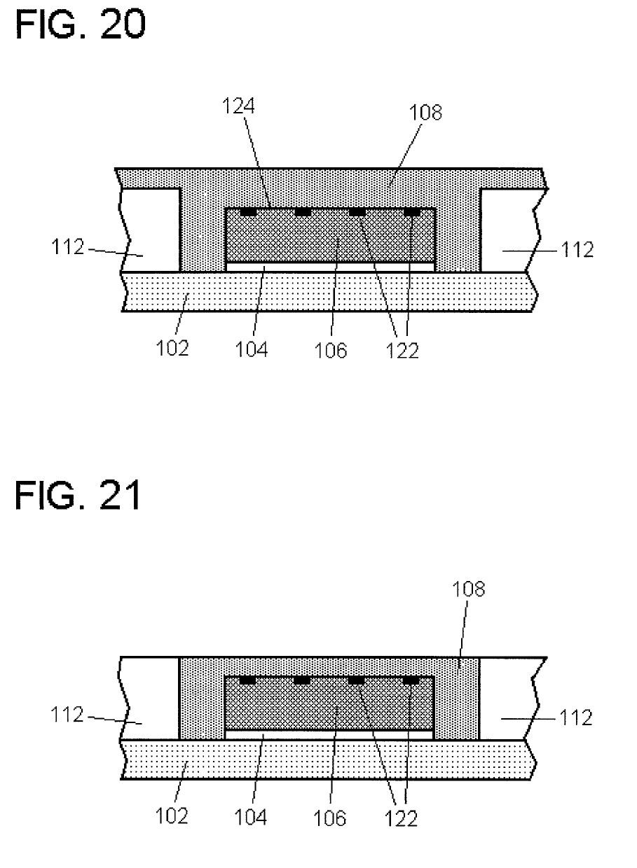

Once the second plurality of conductive traces 136 and the landing pads 138 are formed, they can be used in the formation of conductive interconnects, such as solder bumps, solder balls, pins, and the like, for communication with external components (not shown). For example, a solder mask material 142 can be disposed over the second dielectric layer 132 and the second plurality of conductive traces 136 and landing pads 138, as shown in FIG. 18. A plurality of vias is then formed in the solder mask material 142 to expose at least a portion of each of the landing pads 138. A plurality of conductive bumps 144, such as solder bumps, can be formed, such as by screen printing solder paste followed by a reflow process or by known plating techniques, on the exposed portion of each of the landing pads 138, as shown in FIG. 19. It is, of course, understood that the build-up layer fabrication technique illustrated in FIGS. 12-19 may be used with the microelectronic structure shown in FIG. 4 FIGS. 20 and 21 illustrate another embodiment of the present invention. As shown in FIG. 20, the microelectronic package core 112 is slightly thicker than the microelectronic die 106 with the dielectric encapsulation material 108 disposed over the microelectronic dice 106, the microelectronic package core 112, and in portions of the openings 114 (see FIG. 10) not occupied by the microelectronic die 106. For example, the package core 112 may be about 800 μm thick and the microelectronic die may be between about 725 μm and 775 μm (thickness of 300 mm wafers) thick. An upper portion of the dielectric encapsulation material 108 is removed using techniques such as by etching, by grinding, or by chemical mechanical planarization which stops on the microelectronic package core 112. This provides a substantially uniform thickness of dielectric encapsulation material 108 across the microelectronic die active surface 124. Further fabrication steps are conducted in a similar manner as illustrated and described for FIGS. 13-18.

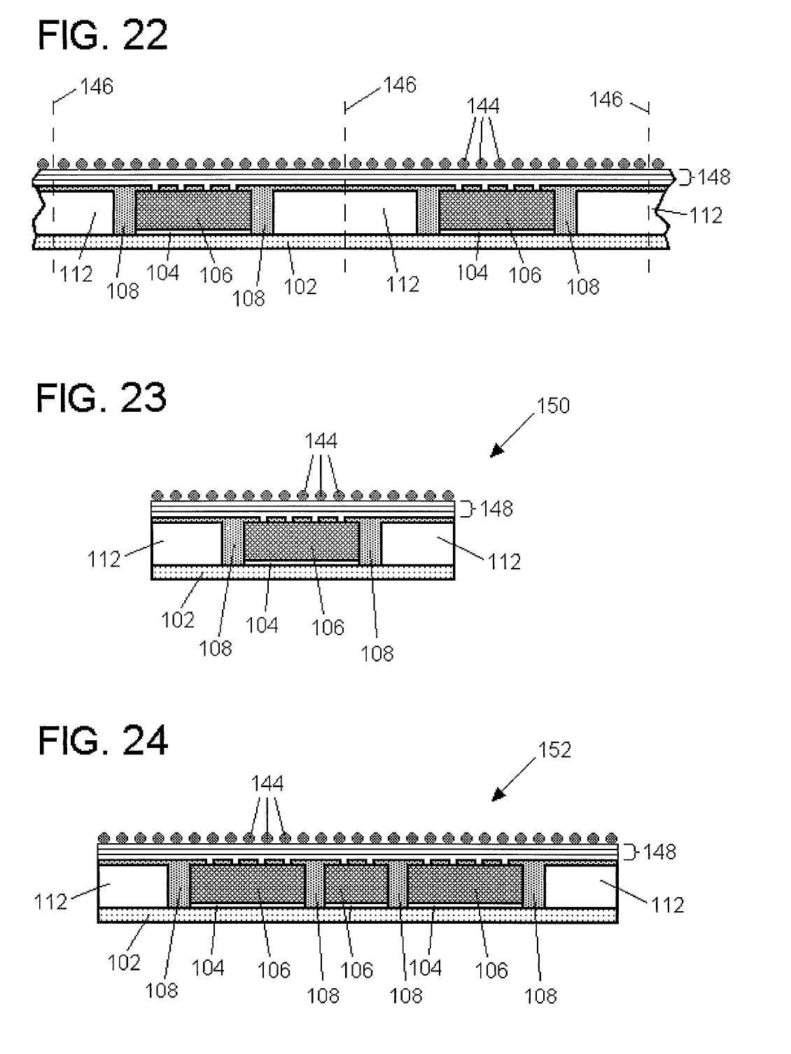

FIG. 22 illustrates a plurality of microelectronic dice 106 encapsulated with the dielectric encapsulation material 108 within the microelectronic package core 112. The individual microelectronic dice 106 may then singulated along lines 146 (cut) through any dielectric layers and traces (designated together as build-up layer 148) and the microelectronic package core 112 to form at least one singulated microelectronic die package 150, as shown in FIG. 23. It is, of course, understood that the plurality of microelectronic dice 106 need not be singulated, but may be left as multi-chip module. Furthermore, the microelectronic dice 106 need not be the same in function or size. Moreover, it is understood that a plurality of microelectronic dice 106, which may differ in size and function, could be encapsulated with the dielectric encapsulation material 108 within a single opening of the microelectronic package core 112 to form a multi-chip module 152, as shown in FIG. 24.

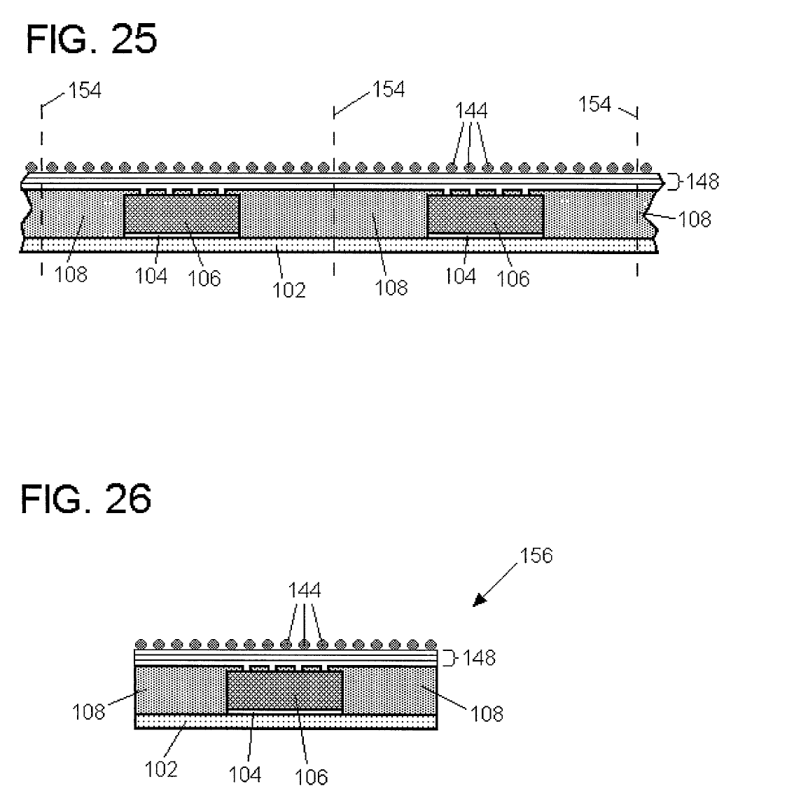

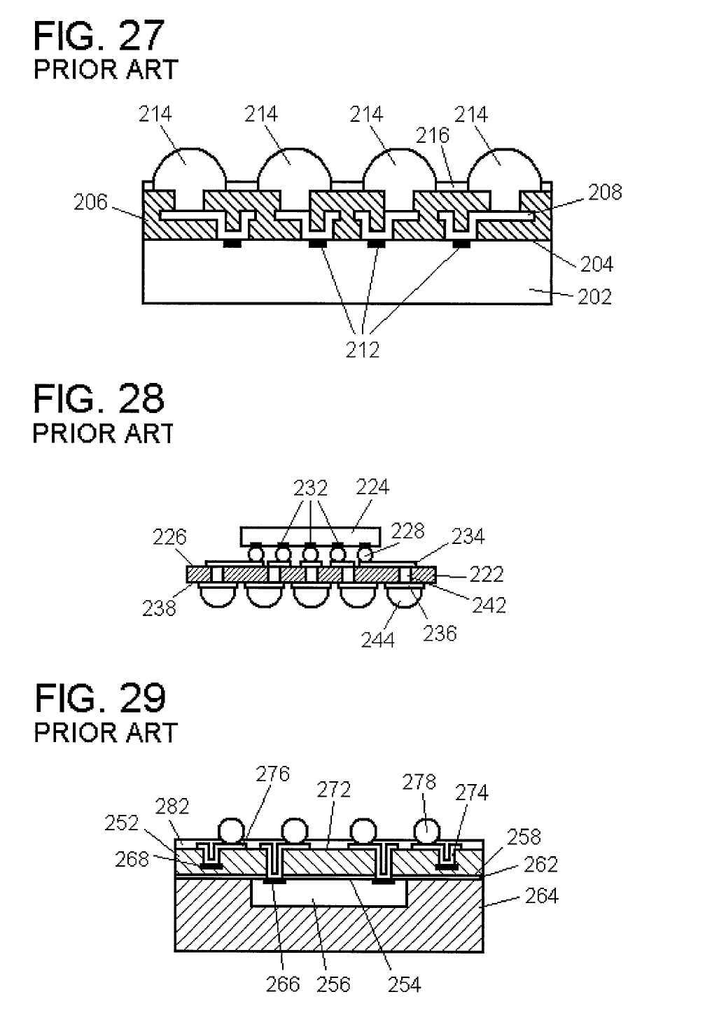

Of course, as illustrated in FIGS. 1-4, the microelectronic package core 112 is optional. Thus, microelectronic dice 106 may simply be encapsulated in the dielectric encapsulation material 108, as shown in FIG. 25. The individual microelectronic dice 106 are then singulated along lines 154 (cut) through the build-up layer 148 and the dielectric encapsulation material 108 to form at least one singulated microelectronic die package 156, as shown in FIG. 26.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A microelectronic package, comprising:
a heat sink;
at least one microelectronic die having an active surface and a back surface, said at least one microelectronic die back surface adjacent to said heat sink; and
an encapsulation material disposed on said heat sink and said microelectronic die active surface.

2. The microelectronic package of claim 1, further including a build-up layer disposed on an upper surface of said encapsulation material.

3. The microelectronic package of claim 2, wherein said build-up layer comprises at least one conductive trace disposed on said encapsulation material upper surface, wherein a portion of said at least one conductive trace extending through said encapsulation material to contact said at least one microelectronic die active surface.

4. The microelectronic package of claim 3, wherein said build-up layer further includes at least one dielectric layer disposed on at least a portion of the encapsulation material upper surface and said at least one conductive trace, and at least one second conductive trace extending through said at least one dielectric layer to contact said at least one conductive trace.

5. The microelectronic package of claim 1, further including a thermally conductive adhesive layer disposed between said at least one microelectronic die and said heat sink.

6. A method of fabricating a microelectronic package, comprising:
providing a heat sink;
disposing a back surface of at least one microelectronic die adjacent to said heat sink;
disposing an encapsulation material on said at least one microelectronic die and said heat sink.

7. The method of claim 6, further including forming a build-up layer on an upper surface of said encapsulation material.

8. The method of claim 7, wherein forming said build-up layer comprises forming at least one via from said encapsulation material upper surface to said at least one microelectronic die active surface and disposing at least one conductive trace on said encapsulation material upper surface, wherein a portion of said at least one conductive trace extending through said at least one via to contact said at least one microelectronic die active surface.

9. The method of claim 8, further including disposing at least one dielectric layer on at least a portion of the encapsulation material upper surface and said at least one conductive trace, forming a via through said dielectric layer, and forming at least one second conductive trace on said dielectric layer, wherein a portion thereof extends through said at least one dielectric layer to contact said at least one conductive trace.

10. A microelectronic package, comprising:
a heat sink;
a microelectronic package core having a first surface and an opposing second surface, said microelectronic package core having at least one opening defined therein extending from said microelectronic package core first surface to said microelectronic package core second surface, where said microelectronic package core second surface abuts said heat sink;
at least one microelectronic die disposed within said at least one microelectronic package core opening and adjacent said heat sink, said at least one microelectronic die having an active surface; and
an encapsulation material disposed on said microelectronic die and in portions of at least one microelectronic package core opening.

11. The microelectronic package of claim 10, further including a build-up layer disposed on an upper surface of said encapsulation material.

12. The microelectronic package of claim 11, wherein said build-up layer comprises at least one conductive trace disposed on said encapsulation material upper surface, wherein a portion of said at least one conductive trace extends through said encapsulation material to contact said at least one microelectronic die active surface.

13. The microelectronic package of claim 12, wherein said build-up layer further includes at least one dielectric layer disposed on at least a portion of the encapsulation material upper surface and said at least one conductive trace, and at least one second conductive trace extending through said at least one dielectric layer to contact said at least one conductive trace.

14. The microelectronic package of claim 11, wherein said encapsulation material covers said microelectronic package core first surface.

15. The microelectronic package of claim 10, wherein a thickness of said microelectronic package core is greater than a thickness of said at least one microelectronic die.

16. The microelectronic package of claim 10, wherein said microelectronic package core is a material selected from the group consisting of bismaleimide triazine resin based material, an FR4 material, polyimides, ceramics, and metals.

17. The microelectronic package of claim 10, further including a thermally conductive adhesive layer disposed between said at least one microelectronic die and said heat sink.

18. A method of fabricating a microelectronic package, comprising:
providing a heat sink;
disposing a back surface of at least one microelectronic die adjacent to said heat sink;
abutting a microelectronic package core adjacent said heat sink, said microelectronic package core having at least one opening defined therein extending from a first surface of said microelectronic package core to a second surface of said microelectronic package core, said at least one microelectronic die residing within said at least one microelectronic package opening;
disposing an encapsulation material on said at least one microelectronic die and in portions of at least one microelectronic package core opening.

19. The method of claim 18, further including forming a build-up layer on an upper surface of said encapsulation material.

20. The method of claim 19, wherein forming said build-up layer comprises forming at least one via from said encapsulation material upper surface to said at least one microelectronic die active surface and disposing at least one conductive trace on said encapsulation material upper surface, wherein a portion of said at least one conductive trace extending through said at least one via to contact said microelectronic die active surface.

21. The method of claim 20, further including disposing at least one dielectric layer on at least a portion of the encapsulation material upper surface and said at least one conductive trace, forming a via through said dielectric layer, and forming at least one second conductive trace on said dielectric layer, wherein a portion thereof extends through said at least one dielectric layer to contact said at least one conductive trace.

22. The method of claim 18, wherein disposing said encapsulation material on said at least one microelectronic die and in portions of at least one microelectronic package core opening comprises disposing said encapsulation material on said at least one microelectronic die, in portions of at least one microelectronic package core opening, and said microelectronic package core first surface.

23. The method of claim 22, wherein abutting a microelectronic package core adjacent said heat sink comprises abutting a microelectronic package core, which is thicker than said at least one microelectronic die, adjacent said heat sink.

24. The method of claim 23, wherein disposing said encapsulation material on said at least one microelectronic die and in portions of at least one microelectronic package core opening comprises disposing said encapsulation material on said at least one microelectronic die, in portions of at least one microelectronic package core opening, and said microelectronic package core first surface.

25. The method of claim 24, further including removing a portion of said encapsulation material on said microelectronic package core forming a uniform thickness of encapsulation material on said at least one microelectronic die.

26. The method of claim 25, further including forming a build-up layer on an upper surface of said encapsulation material.

27. The method of claim 26, wherein forming said build-up layer comprises forming at least one via from said encapsulation material upper surface to said at least one microelectronic die active surface and disposing at least one conductive trace on said encapsulation material upper surface, wherein a portion of said at least one conductive trace extending through said at least one via to contact said microelectronic die active surface.

28. The method of claim 27, further including disposing at least one dielectric layer on at least a portion of the encapsulation material upper surface and said at least one conductive trace, forming a via through said dielectric layer, and forming at least one second conductive trace on said dielectric layer, wherein a portion thereof extends through said at least one dielectric layer to contact said at least one conductive trace.
